(19) United States
(12) Patent Application Publication
(10) Pub. No.: US 2009/0231805 A1
(43) Pub. Date: Sep. 17, 2009

(54) System and Method for Information Handling System Chassis Impact Bumpers

(76) Inventors: Maria Carmen Schlesener, Lago Vista, TX (US); Angela Gail Stern, Round Rock, TX (US)

Correspondence Address: HAMILTON & TERRILE, LLP, P.O. BOX 203518, AUSTIN, TX, 78720, US

(21) Appl. No.: 12/034,831

(22) Filed: Feb. 21, 2008

(51) Int. Cl. G06F 1/16; B29C 45/00; B29C 65/00; B29D 31/00; H05K 13/00

(52) U.S. Cl. 361/679.55; 264/241; 264/255; 428/53; 29/592.1

(57) ABSTRACT

A bumper extending from a portable information handling system chassis aligns with a recess on a lid of the information handling system to maintain the lid in position when the lid closes against the chassis, such as in a closed position or a tablet position. The bumper has a rigid material that couples to the chassis covered at the exposed portion of the bumper by a non-rigid material that interacts with the lid. The non-rigid material absorbs shocks translated through the lid and chassis, and reduces the risk of damage to lid cosmetic features. The rigid portion provides a secure coupling of the bumper to the chassis.

### BACKGROUND OF THE INVENTION

1. Field of the Invention

The present invention relates in general to the field of information handling system chassis, and more particularly to a system and method for information handling system chassis impact bumpers.

2. Description of the Related Art

As the value and use of information continues to increase, individuals and businesses seek additional ways to process and store information. One option available to users is information handling systems. An information handling system generally processes, compiles, stores, and/or communicates information or data for business, personal, or other purposes thereby allowing users to take advantage of the value of the information. Because technology and information handling needs and requirements vary between different users or applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific user or specific use such as financial transaction processing, airline reservations, enterprise data storage, or global communications. In addition, information handling systems may include a variety of hardware and software components that may be configured to process, store, and communicate information and may include one or more computer systems, data storage systems, and networking systems.

Portable information handling systems have received wide acceptance among consumers because, in part, portable systems offer their end users convenience and flexibility. Portable information handling systems typically have an integrated power source, such as a rechargeable battery, and an integrated display, such as a liquid crystal display (LCD). For example, portable information handling systems are built into a chassis having a rotationally coupled lid. The chassis holds most of the processing components that cooperate to process information with a keyboard covering the processing components. The lid holds the LCD and rotates between a closed position in which the lid covers the keyboard and protects the display and an open position in which the keyboard and display are exposed for use. End users appreciate this “clamshell” configuration because portable information handling systems close to a convenient size for ease of transport and open to expose the keyboard and display for ease of use.

Portable information handling systems have recently evolved from the clamshell configuration to also have a tablet configuration. In the tablet configuration, the lid rotates about three axes so that the lid closes with the display exposed. For example, the lid rotates about a horizontal axis to an open position, about a vertical axis so the display faces away from keyboard and then about the horizontal axis so the display closes face up and exposed in a tablet position. In the tablet position, an end user makes inputs through a touchscreen associated with the display, such as with handwriting on the display or activating icons presented at the display. One difficulty with the tablet position is that the display typically must be locked in position so that it does not rotate about the vertical axis when the lid is closed. One way to prevent rotation about the vertical axis is by having bumpers extend from the chassis into a recess of the lid. The lid recesses are formed on both the front and rear of the lid so that rotation about the vertical axis is prevented in the closed position and the tablet position. Typically, the bumpers and the recesses are molded in plastic that forms the chassis and lid. The raised bumpers present a challenge in that ordinary use can sometimes damage or break off a bumper. Another difficulty is that the bumpers point of contact within a recess area provides poor shock absorption along both the vertical and horizontal axes. By molding bumpers within the chassis material, the bumpers can have well-supported thin shapes that extend a good distance into a recess of the lid. Although, the chassis material is typically rigid, which helps to withstand physical damage, the rigid material tends to damage mating parts and cosmetic surfaces when the lid is opened, closed and rotated to and from the tablet position. Further, rigid bumpers extending from chassis proximate to the keyboard palm rest tend to interfere with system use.

### SUMMARY OF THE INVENTION

Therefore a need has arisen for a system and method which secures a tablet information handling system from rotation about a vertical axis with reduced risk of damage to the tablet information handling system.

In accordance with the present invention, a system and method are provided which substantially reduce the disadvantages and problems associated with previous methods and systems for securing a tablet information handling system from rotation about a vertical axis. A bumper extends from a chassis aligned to enter a recess formed in an information handling system lid when the lid closes over top of the chassis. The bumper has a rigid material and a non-rigid material. The rigid material couples to the chassis and supports the non-rigid material exposed at the recess, which provides protection from scraping and a shock absorber for the lid relative to the chassis.

More specifically, an information handling system chassis has a rotationally coupled lid that rotates about a vertical and a horizontal axis between a closed position and a tablet position. The lid has recesses formed on a front side proximate an integrated display and a back side opposite the display. In the closed position, the recesses of the front side align with chassis bumpers extending from the chassis so that engagement of the chassis bumpers in the recess prevents the lid from rotation about the vertical axis. In the tablet position, the recesses of the back side align with the chassis bumpers so that engagement of the chassis bumpers in the recess prevents the lid from rotation about the vertical axis. The chassis bumpers are double shot injection molded so that a rigid material forms the inner portion of the bumper that couples to the chassis and a non-rigid material forms the outer portion of the bumper that engages the lid recess. The inner portion is, for example, made from a hard thermoplastic material that has heat stakes extending into the chassis to support heat staking of the bumper to the chassis. The outer portion is, for example, made from an elastomer material, such as a thermoplastic rubber, that absorbs impacts between the chassis and lid. Two shot injection molding creates a single component having rigid and non-rigid portions integrated with each other for ease of installation and for establishing a strong coupling with reduced risk of breaking.

The present invention provides a number of important technical advantages. One example of an important technical advantage is that a tablet information handling system is secured in closed and tablet positions by bumpers that are securely attached to the chassis yet have a non-rigid surface. The non-rigid surface helps to absorb shock transferred between the lid and chassis and presents less of a nuisance to an end user interacting with the chassis palm rest. The non-rigid surface reduces damage caused to other surfaces of the information handling system during movement of the lid relative to the chassis, such as for moving to and from the tablet configuration. Double shot molding of the bumper securely fixes the non-rigid portion to a rigid underlying portion that is permanently affixed to the chassis to reduce the risk that the bumper will detach from the chassis.

### BRIEF DESCRIPTION OF THE DRAWINGS

The present invention may be better understood, and its numerous objects, features and advantages made apparent to those skilled in the art by referencing the accompanying drawings. The use of the same reference number throughout the several figures designates a like or similar element.

FIG. 1 depicts a front view of a tablet portable information handling system in an open position with chassis bumpers aligned to enter recesses formed in the lid proximate a display;

FIG. 2 depicts a front view of the tablet portable information handling system in an open position having the lid back side rotated towards the front to close to a tablet position with chassis bumpers aligned to enter recesses formed in the lid back side;

FIG. 3 depicts a side view of a portable information handling system having chassis bumpers entered into a lid recess;

FIG. 4 depicts an upper view of a chassis pocket having heat stake openings for accepting a bumper;

FIG. 5 depicts a side cutaway view of a chassis bumper installed in a chassis; and

FIG. 6 depicts a front cutaway view of a chassis bumper installed in a chassis.

### DETAILED DESCRIPTION

Chassis bumpers extending from a tablet portable information handling system into a lid recess with the lid in the closed or tablet configuration prevents rotation of lid about a vertical axis. For purposes of this disclosure, an information handling system may include any instrumentality or aggregate of instrumentalities operable to compute, classify, process, transmit, receive, retrieve, originate, switch, store, display, manifest, detect, record, reproduce, handle, or utilize any form of information, intelligence, or data for business, scientific, control, or other purposes. For example, an information handling system may be a personal computer, a network storage device, or any other suitable device and may vary in size, shape, performance, functionality, and price. The information handling system may include random access memory (RAM), one or more processing resources such as a central processing unit (CPU) or hardware or software control logic, ROM, and/or other types of nonvolatile memory. Additional components of the information handling system may include one or more disk drives, one or more network ports for communicating with external devices as well as various input and output (I/O) devices, such as a keyboard, a mouse, and a video display. The information handling system may also include one or more buses operable to transmit communications between the various hardware components.

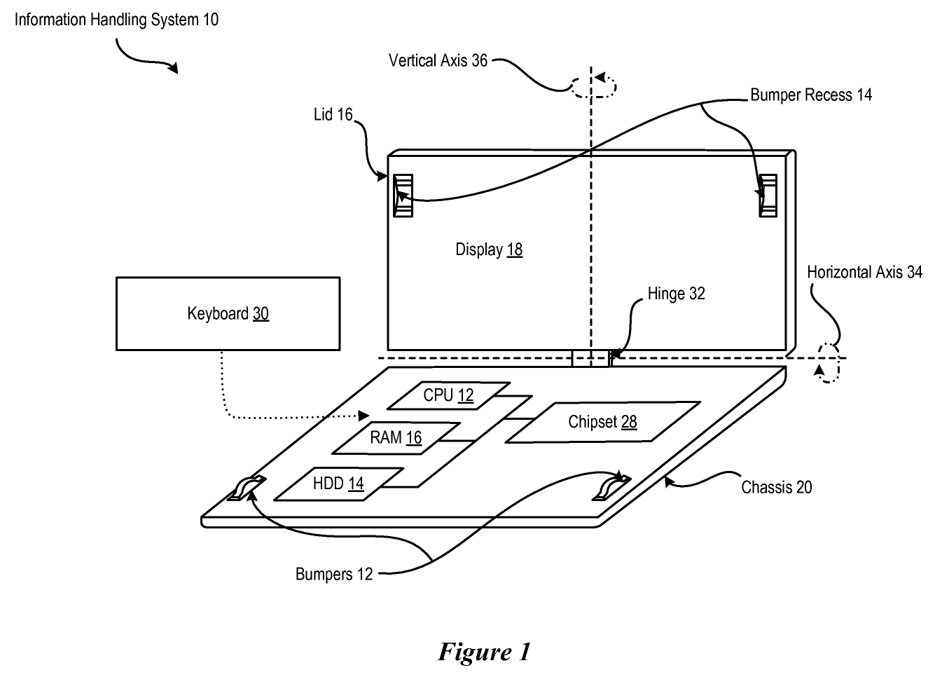

Referring now to FIG. 1, a front view depicts a tablet portable information handling system 10 in an open position with chassis bumpers 12 aligned to enter recesses 14 formed in the lid 16 proximate a display 18. Information handling system 10 is built into a chassis 20 which supports a plurality of processing components that cooperate to process information, such as a CPU 22, a hard disk drive 24, RAM 26 and a chipset 28. A keyboard 30 placed over the processing components accepts inputs from an end user. Lid 16 is rotationally coupled to chassis 20 with a hinge 32 that allows rotation about a horizontal axis 34 and a vertical axis 36. FIG. 1 depicts information handling system 10 in an open configuration with keyboard 30 accessible for inputs by an end user and display 18 visible and facing keyboard 30 for presenting visual displays to an end user. Lid 16 rotates about horizontal axis 34 to a closed position in which display 18 closes over top of keyboard 30 so that bumpers 12 enter into bumper recesses 14. Once bumpers 12 enter into recesses 14, lid 16 is constrained from rotation about vertical axis 36 as long as lid 16 is held proximate to chassis 20

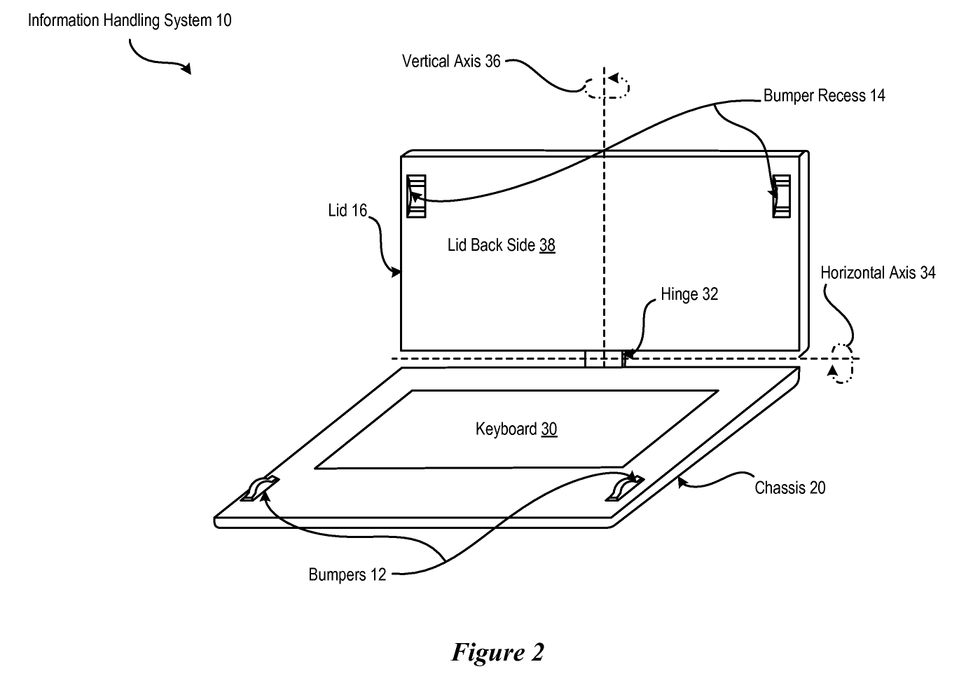

Referring now to FIG. 2, a front view depicts tablet portable information handling system 10 in an open position having lid 16 back side 38 rotated towards the front to close to a tablet position with chassis bumpers 12 aligned to enter recesses 14 formed in lid back side 38. Once lid 16 rotates about horizontal axis 34 so that lid back side 38 closes over keyboard 30, display 18 is exposed for use as a tablet. Engagement of chassis bumpers 12 into bumper recesses 14 formed in lid backside 38 constrains lid 16 from rotation about vertical axis 36 as long as lid 16 is held proximate to keyboard 30, such as by a latch.

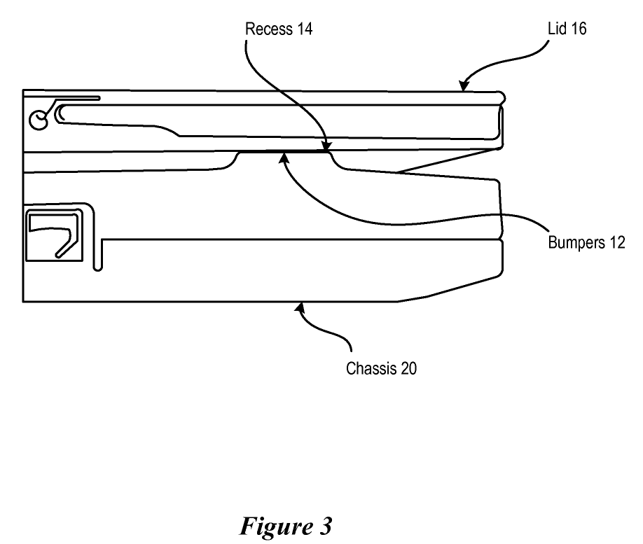

Referring now to FIG. 3, a side view depicts a portable information handling system 10 having chassis bumpers 12 entered into a lid recess 14. Chassis bumper 12 extends outward from chassis 20 towards lid 16 by a distance sufficient to maintain engagement in recess 14 when lid 16 is latched closed to chassis 20. By having recesses formed on both the front and back of lid 16, bumpers 12 prevent rotation in both the closed and tablet positions. Bumpers 12 are built to have a non-rigid material on the outer surface exposed at chassis 20 so that lid components coming in contact with bumpers 12 are not subjected to damaging impacts and so that end user interaction with bumpers 12 will not injure the end user. Bumpers 12 are built with a rigid material where the inner surface contacts chassis 20 to ensure good coupling and to reduce the risk of a bumper 12 breaking off.

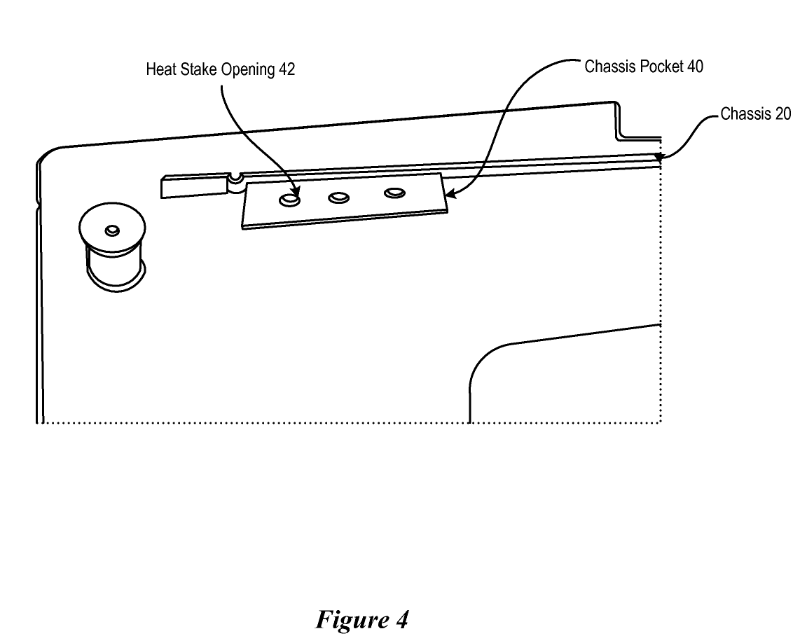

Referring now to FIG. 4, an upper view depicts a chassis pocket 40 having heat stake openings 42 for accepting a bumper 12. During manufacture of information handling system 10, chassis pocket 40 is formed in chassis 20 to accept a bumper 12. In the example depicted by FIG. 4, three heat stake openings 42 are formed to accept heat stakes of the bumper for heat staking the bumper to chassis 20. Chassis pocket 40 has dimensions so that the rigid material of the bumper fits with in pocket 40 and substantially only the non-rigid portion of the bumper is exposed after the bumper couples to chassis 20. Although heat staking provides a method for secure attachment of the bumper, other types of securing techniques might be employed to ensure adequate attachment of the bumper to chassis 20.

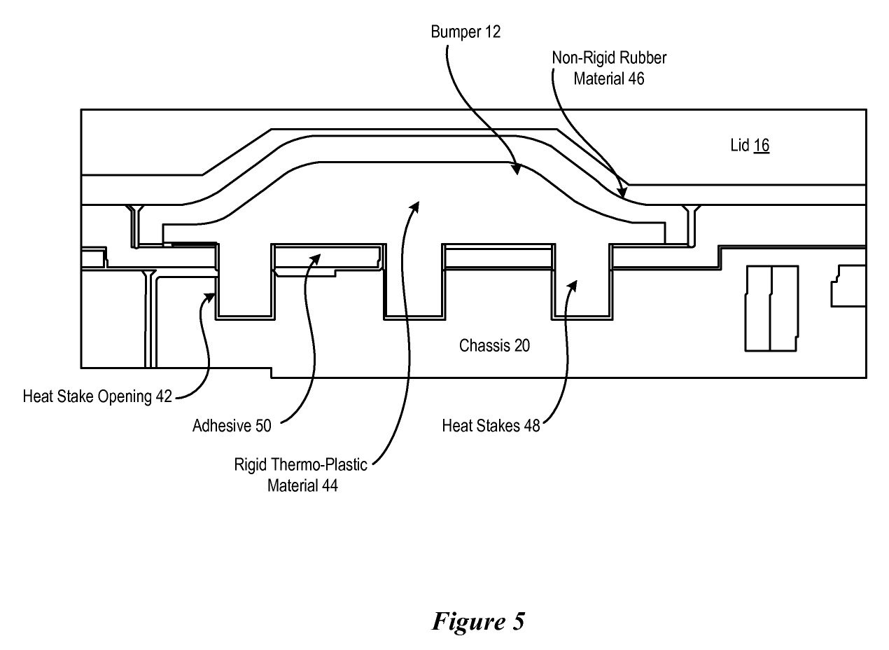

Referring now to FIG. 5, a side cutaway view depicts a chassis bumper 12 installed in a chassis 20. Chassis bumper 12 has a rigid material 44 that couples proximate to chassis 20 and a non-rigid material 46 that covers rigid material 44 where bumper 12 is exposed from chassis 20 proximate to lid 16. For example, rigid material 44 is a hard thermoplastic and non-rigid material 46 is a rubber or other elastomer thermoplastic. Rigid material 44 and non-rigid material 46 are cast together as a single component, such as with two shot injection molding. Rigid material 44 is cast to include heat stakes 48 that extend into heat stake openings 42 formed in chassis 20. During manufacture, an adhesive 50 holds bumper 12 in place while the heat stake process is performed to couple rigid material 44 to chassis 20.

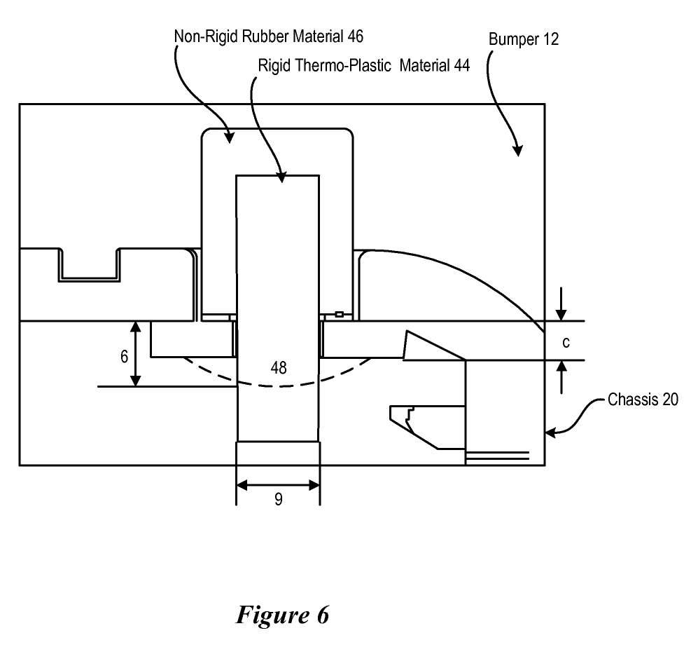

Referring now to FIG. 6, a front cutaway view depicts a chassis bumper 12 installed in a chassis 20. In the example embodiment depicted by FIG. 6, chassis bumper 12 has a total thickness of approximately 2 mm with non-rigid material 46 having a thickness of approximately 0.5 mm enclosing rigid material having a width of approximately 1 mm. Chassis 20 forms a molded wall to accept bumper 12, with the thickness c of the molded wall approximately 0.6 mm to help retain bumper 12 within chassis 20. Total thickness of heat stake 48 is approximately 1 mm to retain bumper 12 in chassis 20 with reduced risk of breaking. The height b of the heat stake within chassis 20 is approximately 1 mm to retain heat stake 48 within chassis 20.

Although the present invention has been described in detail, it should be understood that various changes, substitutions, and alterations can be made hereto without departing from the spirit and scope of the invention as defined by the appended claims.

1. An information handling system comprising:
a chassis;
plural processing components disposed in the chassis, the processing components operable to process information;
a lid rotationally coupled to the chassis, the lid having one or more recesses;
a display integrated in the lid and interfaced with the processing components, the display operable to present the information as visual images; and
one or more bumpers extending from the chassis and aligned to insert in the one or more lid recesses, the bumpers having a rigid portion coupled to the chassis and a non-rigid portion covering the rigid portion extending from the chassis.

2. The information handling system of claim 1 wherein the rigid portion couples to the chassis by heat staking.

3. The information handling system of claim 1 wherein the bumper comprises a two-shot injection molded component, the non-rigid portion molded by a first shot with a first material, the rigid portion molded by a second shot with a second material.

4. The information handling system of claim 3 wherein the first material comprises an elastomer.

5. The information handling system of claim 1 wherein the lid rotationally couples to the chassis to move between a closed position and a tablet position, the lid having a back side exposed in the closed position and a front side exposed in the tablet position, at least one recess formed on the back side to align with the bumper in the closed position and at least one recess formed on the front side to align with the bumper in the tablet position.

6. The information handling system of claim 6 wherein the display comprises a touch screen.

7. The information handling system of claim 1 wherein the bumper comprises one or more heat stake posts extending from the rigid portion into the chassis.

8. A method for manufacture of an information handling system chassis, the method comprising:
forming a chassis having a pocket;
forming a bumper sized to couple in the chassis pocket, the bumper having a rigid portion integrated with a non-rigid portion;
coupling the rigid portion to the chassis in the pocket to expose substantially only the non-rigid portion at the chassis.

9. The method of claim 8 wherein forming a bumper comprises forming the bumper with double shot injection molding having a rigid material and a non-rigid material.

10. The method of claim 9 wherein the rigid material comprises a thermoplastic and the non-rigid material comprises a rubber.

11. The method of claim 8 wherein coupling the rigid portion comprises heat staking the rigid material to the chassis.

12. The method of claim 11 wherein coupling the rigid portion further comprises using an adhesive to hold the rigid portion in place for heat staking.

13. The method of claim 8 further comprising:
forming a lid having a front and a back, the lid further having a recess in the front, the recess aligning with the bumper when the lid couples to the chassis in a closed position; and
rotationally coupling the lid to the chassis.

14. The method of claim 13 wherein forming a lid further comprises forming the lid to have a recess in the back, the recess aligning with the bumper when the lid couples to chassis in a tablet position and wherein rotationally coupling the lid further comprises coupling the lid to rotate in horizontal and vertical axes.

15. The method of claim 14 further comprising integrating a touch screen in the lid, the touch screen exposed in the tablet configuration.

16. A system for managing the position of a rotationally-coupled lid relative to an information handling system chassis, the system comprising:
a bumper having a rigid portion integrated with a non-rigid portion, the rigid portion adapted to couple to the information handling system chassis, the non-rigid portion adapted to fit into a recess formed in the lid.

17. The system of claim 16 further comprising heat stakes extending outward from the rigid portion, the heat stakes operable to couple to the chassis.

18. The system of claim 16 wherein the rigid portion comprises a thermoplastic and the non-rigid portion comprises a rubber, the thermoplastic and rubber integrated with a two shot injection molding.

19. The system of claim 16 wherein the recess formed on the lid comprises a recess on a front side of the lid, the bumper aligned to fit in the recess with the information handling system in a closed position.

20. The system of claim 19 wherein the recess formed on the lid comprises a recess on a back side of the lid, the bumper aligned to fit in the recess with the information handling system in a tablet position.
